(19) United States
(12) Patent Application Publication
(10) Pub. No.: US 2002/0124997 A1
(43) Pub. Date: Sep. 12, 2002

(54) Cooling system for a power electronics module to drive at least on electrical unit in a motor vehicle

(76) Inventor: Frank Blome, Geeste (DE)

Correspondence Address: BLAKELY, SOKOLOFF, TAYLOR & ZAFMAN LLP, Seventh Floor, 12400 Wilshire Boulevard, Los Angeles, CA, 90025-1026, US

(21) Appl. No.: 09/733,845

(22) Filed: Dec. 8, 2000

Related U.S. Application Data
(63) Continuation of application No. PCT/EP99/04141, filed on Jun. 15, 1999.

(30) Foreign Application Priority Data
Jun. 16, 1998 (DE) 198 26 733.9

(51) Int. Cl. F28D 15/00; H05K 7/20; H01L 23/34

(52) U.S. Cl. 165/104.21; 361/700; 257/715

(57) ABSTRACT

The invention is directed to a cooling system for a power electronics module to drive at least one unit in a motor vehicle, in particular a starter motor/generator, with a pressure sealed compartment (2) for housing an electronic assembly (1) and a bath (3) of electrically isolating primary coolant surrounding this, boiling, at operating pressure, at a temperature which does not exceed the permissible operating temperature of the electronic assembly (1), and a heat exchanger (5), fitted above the meniscus of the primary coolant or linked to it by means of a connecting assembly (9), whereby the primary coolant vaporized in the electronic assembly (1) reaches the heat exchanger (5) as vapor, there condenses and returns to the bath (30, thus providing circulation of the primary coolant. A secondary cooling circuit with a secondary coolant, has a cooler (8) cooling the heat exchanger (5). The secondary cooling circuit (6) has at least one low point for the coolant below the level of the heat exchanger (5) and a pump (7) to force a circulating flow of the secondary coolant.

### FIELD OF THE INVENTION

This is a continuation of PCT/EP99/04141 filed on Jun. 15, 2000, which claims priority from German Patent Application No. 198 26 733.9 filed on Jun. 16, 1998.

The present invention relates to a cooling system for a power electronics module to drive at least one electrical unit in a motor vehicle, in particular to drive a starter motor/generator of a motor vehicle.

### BACKGROUND OF THE INVENTION

There are a significant number of power consuming devices on conventional motor vehicles, such as the valve train for the internal combustion engine, an air conditioning compressor, braking booster, power assisted steering and other similar fittings. Of these, only certain devices, consuming relatively little power, are electrically operated, such as the window drives, central locking system, sunroof and folding top. Only the electric starter motor has a power consumption of several kW, which is, nonetheless, required only for sporadic operations lasting a very short time, not least because the vehicle battery capacity only allows operation for a very short period.

Moreover, power consuming devices are linked to the main power train, which powers them via the driveshaft (valve train, air conditioning compressor) or secondary vacuum pressure (braking booster). In sum, therefore, significant power consuming devices are frequently linked mechanically or pneumatically with the main power train, the linkage frequently being elaborately implemented and greatly limiting fitting options (for the power consuming devices). Variable operating modes—perhaps in the case of the valve train—are rendered difficult with this type of linkage, an optimum degree of efficiency (such as with the air conditioning compressor) being hard to achieve, in view of the mainly fixed rotating coupling.

A further disadvantage of the conventional modus operandi described is that the power consuming devices cannot be used if the main power train is not running. This creates problems when implementing automatic Start-Stop operation—particularly desirable from the environmental protection point of view—as well as towing vehicles when the motor of the towed vehicle is not running.

The problems outlined above would be resolved if the vehicle's electrical system were designed to be capable of providing significantly greater power, for the power consuming devices could then be driven electrically. They could then also be mounted in the most appropriate position on the vehicle, since a mechanical linkage with the main power train, as employed previously, would certainly no longer be required, and provide variable operation with greater efficiency. The dynamo previously employed would be replaced by a larger generator with a power output of several kilowatts, also usable as the starter motor, so the latter would no longer be needed.

In addition to simplifying the construction quite significantly, this would also provide the option of driving the power consuming devices even if the main power train is not in service, provided the battery capacity available is sufficient. It would also be simpler to implement automatic Start-Stop operation.

With a suitably dimensioned electrical system, it would also be possible to power new types of fitting, which have hitherto been almost impossible to achieve in practice, such as an electro-magnetic valve train, a separate electrical coolant heating system for the vehicle, giving cold starting in winter with less wear and tear on the engine, or an electrical catalyser pre-heating system to avoid emission of pollutants in the engine warm-up phase. The weight saving achieved by discarding the previous mechanical drive linkages would compensate, at least in part, for the increased weight of a more powerful battery.

Losses in individual power consuming devices could also be optimised, because their pattern of operation could be better adapted to the requirement; for example, an air conditioning compressor could be driven at constant speed to maximise its efficiency. However, a correspondingly more powerful generator, with the associated power electronics module, is required for an appropriately dimensioned electrical system, as is known, for example, from WO97/08456. The generator described in this document is an electrical AC machine, acting also as the starter motor for the internal combustion engine. Essentially, the power electronics module is a transformer with power transistor switching, producing three phase magnetic braking fields when the generator is running, converting the alternating current supplied by the machine to direct current with the aid of the power transistor switches. When the engine is running, it generates three phase magnetic driving fields, the alternating current required for this purpose being produced from direct current with the aid of the power transistor switches.

Compared with the electrical machine, the power electronics module itself has a significant cooling requirement. If the standing power is about 20 kW, with power transistor losses of 2%, then there is a requirement to absorb 400 W of cooling power. In order for compact construction of the power electronics module to be achievable, despite this high cooling power, “boiling bath” cooling is employed. For example, an electrically non-conducting chlorofluorocarbon is employed as the coolant, circulating round the closely packed components of the power electronics module, these in their turn laid out in a pressure-sealed compartment. If the local temperature reaches the boiling point of the coolant, and this is fed with further heat, it vaporises as it absorbs the latent heat, and the vapour clouds formed at the same time rise immediately by virtue of their buoyancy, permitting unvaporised coolant to reach the position to be cooled. In an air cooler, the vapour gives up the latent heat absorbed and simultaneously condenses. The fluid flows back to the compartment, where the cooling cycle begins afresh.

As the vapour can only reach the cooler by virtue of its buoyancy, and the condensate corrspondingly reach the compartment, the cooler must be fitted above the compartment housing the power electronics module. This boundary condition, which cannot be circumvented, can make finding a suitable mounting position extremely difficult. In motor vehicles, however, the question of where to house units often has a deciding role as a direct result. These types of difficulty must have been among the reasons why the modern power electronics module—even though it has been known for over two decades—has not previously been employed more widely in motor vehicles.

A corresponding “boiling bath” cooling system is known in general terms, for example from DE 42 30 510 C1.

DE 32 36 612 C2 discloses an application in the railways area, in which, during long journeys through tunnels, with correspondingly high outside temperatures, a heat accumulator provides an additional reverse cooling option. For this purpose, a secondary cooling circuit, giving up its heat to a water storage tank, provides cooling for the condenser.

### SUMMARY OF THE INVENTION

The invention provides a cooling system for a power electronics module to drive at least one electrical unit in a motor vehicle, in particular a starter motor/generator. The cooling system comprises a pressure sealed compartment for housing an electrical assembly and a bath of electrically isolating primary coolant surrounding this, boiling, at operating pressure, at a temperature which does not exceed the maximum permissible operating temperature of the electronic assembly; a heat exchanger, fitted above the meniscus of the primary coolant, or linked with this by means of a connecting device, whereby primary coolant vaporised in the electrical assembly reaches the heat exchanger as vapour, there condenses and flows back to the bath, thus providing circulation of the primary coolant; and a secondary cooling circuit, with a secondary coolant, having a cooler cooling the heat exchanger. The secondary cooling circuit has at least one low point for the coolant below the level of the heat exchanger. The secondary cooling circuit has a pump to force a circulating flow of the secondary coolant.

Other features are inherent in the cooling system or will become apparent to those skilled in the art from the following detailed description of embodiments and its accompanying drawings.

### DESCRIPTION OF THE DRAWINGS

In the accompanying drawings:

FIG. 1 is a schematic representation of a first embodiment, with a low point in the connections for a secondary cooling circuit, and

FIG. 2 is a schematic representation of a second embodiment, in which a cooler for the secondary cooling circuit is lower than the fluid meniscus of a primary coolant.

In both figures, identical reference designations indicate identical or similar elements or modules.

### DETAILED DESCRIPTION OF THE PREFERRED EMBODIMENTS

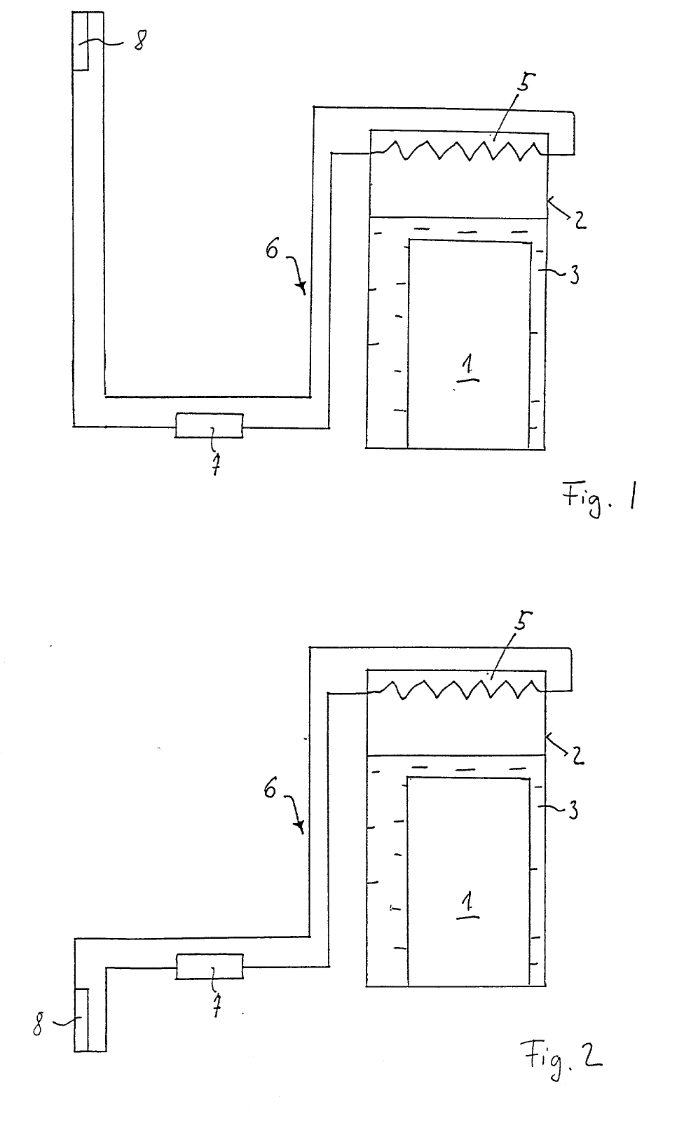

The devices shown in FIGS. 1 and 2 are installed in a motor vehicle. Before proceeding further with the description of FIG. 1, a few items of the preferred embodiments will be discussed.

In the disclosed embodiments, the cooling circuit does not, as was previously necessary, always have to be fed upwards to a cooler; instead, it has a lowest point below the level of the fluid meniscus of the coolant for the power electronics module.

The provision of a secondary cooling circuit and the availability of a low point imply significantly greater freedom in the cooler configuration, for, in conventional solutions, this could only be fitted in an area of the motor vehicle which could be reached exclusively via an upward link with the power electronics module. The disclosed embodiments negate the requirement for an exclusively ascending link. In the first embodiment of FIG. 1, for example, the link follows a descending path initially and ascends to a cooler only after passing beneath an obstruction. The level of the cooler is so arranged as to be above the power electronics module. In the second embodiment of FIG. 2 the cooler is, however, below the level of the power electronics module, thus itself forming the low point. If necessary, further low points can also be in the feed.

In the preferred embodiments the heat exchanger, forming a condenser to cool the primary coolant vapour, is sited for choice in or on the pressure sealed compartment, for example internally, directly above the fluid meniscus. In other embodiments (not shown) it is sited opposite the compartment and linked to this via a connecting device.

Thus, in the preferred embodiments, the heat exchanger is within, or on, the sealed compartment, on whose external surface there are then, in addition, electrical connections (preferably only two pipe or hose connections) which must be connected to the secondary cooling circuit. This design has the advantage that, during installation or exchange, other than manufacturing the electrical connections, the only task is to connect the pipework for the secondary cooling circuit (in general, operated at the surrounding pressure); the encapsulated compartment containing the electronic assembly, a rule maintained at an internal pressure below that of its surroundings, for the purpose of regulating the boiling point, requires no further work other than installation and connection.

In the other embodiments, the heat exchanger is sited opposite the sealed compartment and connected with it via two leads, for vapour and condensed coolant respectively.

In the disclosed embodiments a pump to initiate and maintain forced coolant circulation is supplied in the connection system of the secondary cooling circuit so that, despite descending connecting sections, the passage of coolant heated in the heat exchanger to the cooler, and coolant cooled in this latter back to the heat exchanger once more, is assured. The secondary coolant is, for example, water.

The power electronics module may thus be fitted at the most appropriate point in the motor vehicle, with the cooler and, as required, the heat exchanger, being installed in their turn at particularly suitable positions, perhaps providing a particularly beneficial cooling air stream for the cooler, unless leads must be fitted so as to prevent a flow of cooling air.

The disclosed embodiments allow leads connecting the compartment with the heat exchanger or a cooler to be fitted freely and without any loading, for example on walls or the lower edge of the engine compartment, so that, perhaps when installing and dismantling the engine and other units, they are not in the way and must then be correspondingly installed and dismantled, as well as requiring to be drained and refilled with water or coolant.

As a result, the disclosed embodiments make employment of power electronics modules in the motor vehicle more practicable. In a motor vehicle fitted out in this manner, the internal combustion engine forming the main power train has the benefit, instead of mechanical and pneumatic connections, of only a single electrical machine, performing the functions of both generator and starter motor, permanently geared to the engine forming the main power-train, and capable even of being incorporated in its construction—for example between the engine and the gearbox.

In the disclosed embodiments, the secondary cooling circuit also has a heat exchanger, termed the “cooler”. It is preferred for this cooler to be air cooled. It is then no longer necessary to demand cooling air for the cooler; rather, the cooler may be mounted where there is a cooling air current, for example at a point where it is exposed to the wind due to the vehicle's motion, or behind the prime mover fan. However, it is equally possible to provide the cooler with its own electric fan. As a space saving expedient, for example, the space below the cooler for the prime mover is preferable, so that the cooler, if it is fitted there, is then also fitted at the, or at least a. coolant low point.

According to choice, the pump for the secondary cooling circuit may be fitted either in the colder or warmer branch.

Turning now again to FIG. 1, a power electronics module 1, indicated only by a box, is fitted in the lower part of a pressure sealed compartment 2. (Expressions such as “high” and “low” refer to the buoyancy direction relative to the position in which the cooling system would normally be fitted.) In this instance, it represents a transformer with power transistor switching for control of a three phase electrical machine, employed as a generator suitable for powering electrical high performance power consuming devices, as well as performing the duty of a starter motor for the motor vehicle's internal combustion engine. The transformer produces three phase braking magnetic fields and thus converts the alternating current supplied by the machine to direct current with the aid of the power transistor switches. When the engine is running, it generates three phase driving magnetic fields, the alternating current required for this purpose being produced from direct current with the aid of the power transistor switches.

The power electronics module is completely immersed in a bath 3 of an electrically isolating fluid, whose boiling point is lower than the maximum permissible operating temperature of the components in the power electronics module 1. This might be a chlorofluorocarbon having a boiling point of 60° C. at an operating pressure of about 2 bar. When the power electronics module 1 is in operation, the temperature of the power transistors rises to boiling point as a result of the semiconductor heat losses and, at these points, brings the coolant in bath 3 to the boil, giving off a significant quantity of heat in order to vaporise the coolant. The vapour thus formed rises.

In the embodiment shown, a heat exchanger 5 is embodied in the upper face of the compartment 2 and hermetically sealed. The underside of this heat exchanger 5 is exposed to the inner surface of the compartment 2; the vapour thus has direct access to its heat sink and condensed coolant drips from it back into the bath. In other (not shown) design forms, the heat exchanger is a separate component, fitted above the compartment and linked to the compartment via piped connections routed exclusively upwards. In further (again, not shown) design forms the heat exchanger is embodied in the compartment, yet separated from it by an intermediate base provided with a vapour inlet; the condensed coolant can then be collected and fed back to the bath via an outlet, for example formed as an immersion pipe just protruding above the base of the compartment.

A lead in thermal contact with a secondary coolant, linked to a secondary cooling circuit 6, passes through the heat exchanger 5. In operation, the primary coolant in compartment 2 vaporises, ascends to the heat exchanger due to its buoyancy alone (thus without the aid of a pump et al), there condenses and flows back to the bath 3.

The secondary cooling circuit 6 has one connection leading from the heat exchanger 5 to a cooler 8 and another leading from the cooler 8 to the heat exchanger 5, in which is fitted a recirculating pump 7 to force the circulation of the secondary coolant in the secondary cooling circuit. The cooler 8 is cooled by the wind due to the vehicle's motion or by means of a fan (not shown). Thus, the heat absorbed due to the vaporisation of the primary coolant is finally given up to the surrounding air via the cooler 8. In the case of the secondary coolant, this may, for example, relate to water. In this case, there is no need for a change between liquid and vapour phases to assist the heat transfer and transport, as the heat absorbed by the secondary coolant in the fluid phase is generally sufficient.

The pipework for the secondary cooling circuit leads to at least one point which is lower than the meniscus of the primary coolant. This allows a blocking component in the motor vehicle to cross the direct path. In the embodiment of FIG. 2, the cooler 8 is lower than the meniscus of the primary coolant and thus itself forms the “nadir” of the secondary cooling circuit. This allows the cooler to be fitted at a suitably low level in the motor vehicle.

In many cases, it is thus possible, even in the narrow confines of a motor vehicle, to mount the cooling system, with no further measures, such that both the cooler 8 and the power electronics module 1 can be fitted respectively in their optimum individual positions.

Thus, a general purpose of the disclosed embodiments is to provide a cooling system for a power electronics module which saves space and whose location is, to a large extent, freely selectable; hence the space in the vehicle not available for people or freight may be reduced in size.

Although certain methods, systems and products constructed in accordance with the teachings of the invention have been described herein, the scope of coverage of this patent is not limited thereto. On the contrary, this patent covers all embodiments of the teachings of the invention fairly falling within the scope of the appended claims either literally or under the doctrine of equivalents.

What is claimed is:

1. A cooling system for a power electronics module to drive at least one electrical unit in a motor vehicle, in particular a starter motor/generator, comprising
a pressure sealed compartment (2) for housing an electrical assembly (1) and a bath (3) of electrically isolating primary coolant surrounding this, boiling, at operating pressure, at a temperature which does not exceed the maximum permissible operating temperature of the electronic assembly (1),
a heat exchanger (5), fitted above the meniscus of the primary coolant, or linked with this by means of a connecting device (9), whereby primary coolant vaporised in the electrical assembly (1) reaches the heat exchanger (5) as vapour, there condenses and flows back to the bath (3), thus providing circulation of the primary coolant,
a secondary cooling circuit, with a secondary coolant, having a cooler (8) cooling the heat exchanger (5), he secondary cooling circuit (6) having at least one low point for the coolant below the level of the heat exchanger (5) and the secondary cooling circuit (6) having a pump (7) to force a circulating flow of the secondary coolant.

2. The cooling system of claim 1, wherein the low point coolant is formed by the cooler (3).

3. The cooling system of claim 1, wherein the heat exchanger (5) is fitted in or on the compartment (2).

4. The cooling system of claim 1, wherein the cooler is cooled by means of a current of air.
